(19) United States
(12) Patent Application Publication
(10) Pub. No.: US 2012/0211782 A1
(43) Pub. Date: Aug. 23, 2012

(54) ORGANIC ELECTROLUMINESCENT ELEMENT AND DISPLAY INCLUDING SAME

(75) Inventors: Yojiro Matsuda, Kawasaki-shi (JP); Nobutaka Mizuno, Mobara-shi (JP); Norifumi Kajimoto, Chiba-shi (JP)

(73) Assignee: CANON KABUSHIKI KAISHA, Tokyo (JP)

(21) Appl. No.: 13/503,769

(22) PCT Filed: Oct. 22, 2010
(86) PCT No.: PCT/JP2010/069235

§ 371 Date: Apr. 24, 2012

(30) Foreign Application Priority Data
Nov. 4, 2009 (JP) 2009-253076
Sep. 29, 2010 (JP) 2010-219483

(51) Int. Cl. H01L 51/52

(52) U.S. Cl. 257/89; 257/99; 257/E51.019

(57) ABSTRACT

An organic electroluminescent element includes a first electrode, an organic compound film including a plurality of layers that include an emissive layer, a second electrode, a protective layer, and a buffer layer formed by an evaporation method between the second electrode and the protective layer, light emitted from the emissive layer emerging from the second electrode side, in which the second electrode is formed of a metal film having a thickness of 5 nm to 20 nm, a distance between a surface of the emissive layer adjacent to the first electrode and a surface of the second electrode adjacent to the organic compound film is in the range of 55 nm to 90 nm, and the protective layer is formed by a sputtering method or a plasma-enhanced chemical vapor deposition method.

### TECHNICAL FIELD

The present invention relates to an organic electroluminescent element (hereinafter, referred to as an “organic EL element”) and a display including the organic electroluminescent element.

### BACKGROUND ART

Organic EL elements each include a lower electrode arranged on the substrate side, an organic compound film including an emissive layer, and an upper electrode, which are stacked. The efficiency of light emission of organic EL elements has been required to be improved. To this end, a top-emission organic EL element has been provided in which light emerges from a side (upper electrode side) opposite a substrate in which thin film transistors are formed. Furthermore, an organic EL element has been provided in which two electrodes included in an organic EL element are composed of a metal and the efficiency of light emission is improved by means of optical interference that increases the intensity of light between the two electrodes owing to high reflectivity of metal.

An organic EL element is sensitive to water and thus is covered with a protective layer configured to prevent penetration of water. PTL 1 discloses a protective layer composed of silicon nitride formed by chemical vapor deposition (CVD) on an organic EL element.

### CITATION LIST

### Patent Literature

PTL 1 Japanese Patent Laid-Open No. 64-41192

### SUMMARY OF INVENTION

### Technical Problem

For a top-emission organic EL element that uses optical interference, however, it was found that the formation of a protective layer by a sputtering method or a plasma-enhanced CVD method, which is a high-energy film-forming method, significantly degrades the life properties of the organic EL element. The reason for this is as follows: In the organic EL element described above, the upper electrode is formed of a thin metal film having a thickness of 20 nm or less. Thus, high energy applied during the formation of the protective layer is transferred to the organic compound film arranged between the electrodes, damaging the organic EL element. Furthermore, the layers from the emissive layer to the upper electrode are typically formed in a small thickness such that an optical distance between an emission point in the emissive layer and the upper electrode is set to about ¼ of an emission wavelength because of the use of optical interference. Thus, damage to the emissive layer is problematic.

### Solution to Problem

According to aspects of the present invention, an organic electroluminescent element includes a first electrode, an organic compound film including a plurality of layers that include an emissive layer, a second electrode, a protective layer, and a buffer layer formed by an evaporation method between the second electrode and the protective layer, light emitted from the emissive layer emerging from the second electrode side, in which the second electrode is formed of a metal film having a thickness of 5 nm to 20 nm, a distance between a surface of the emissive layer adjacent to the first electrode and a surface of the second electrode adjacent to the organic compound film is in the range of 55 nm to 90 nm, and the protective layer is formed by a sputtering method or a plasma-enhanced chemical vapor deposition method.

### Advantageous Effects of Invention

Aspects of the present invention provide an organic EL element having satisfactory life properties by reducing damage from high energy applied during the formation of a protective layer.

### BRIEF DESCRIPTION OF DRAWINGS

FIG. 1 is a cross-sectional view of an organic EL element according to an aspect of the present invention.

FIG. 2 is a cross-sectional view of an organic EL element according to another aspect of the present invention.

FIGS. 3A and 3B are cross-sectional views of organic EL elements according to other aspects of the present invention.

FIG. 4 is a display according to aspects of the present invention.

### DESCRIPTION OF EMBODIMENTS

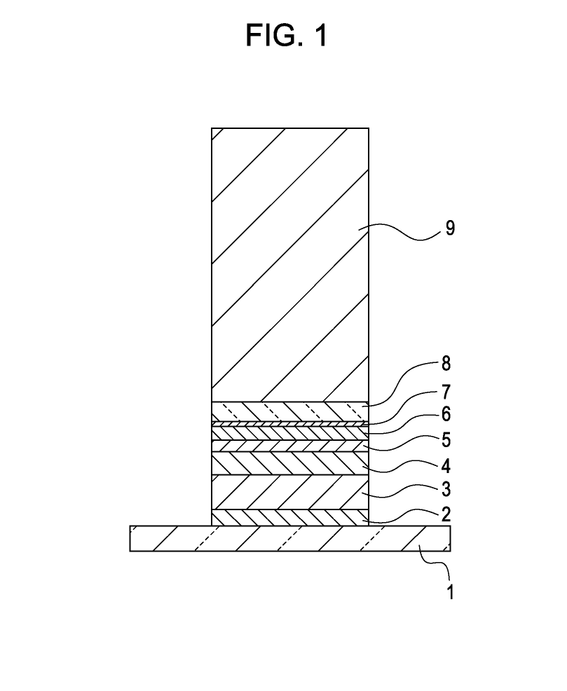

Embodiments of an organic EL element according to aspects of the present invention will be described below with reference to FIG. 1. A top-emission organic EL element illustrated in FIG. 1 includes a first electrode 2, an organic compound film including a hole transport layer 3, an emissive layer 4, an electron transport layer 5, and an electron injection layer 6, a second electrode 7, a buffer layer 8, and an inorganic protective layer 9 stacked, in that order, on a substrate 1. Holes and electrons injected from two electrodes by the energization of the organic EL element are recombined in the emissive layer 4 to produce energy. The organic EL element emits light using the energy. In the organic EL element according to aspects of the present invention, light emerges from the second electrode side opposite the substrate.

The top-emission organic EL element according to aspects of the present invention has an optical cavity structure. Specifically, the following two constructive optical interferences are used. One is an optical interference in which each of the first electrode 2 and the second electrode 7 has a metal layer and in which light generated in the emissive layer 4 is reflected between a reflecting surface of the first electrode and a reflecting surface of the second electrode 7, whereby the reflected light is reinforced. The relationship among parameters, including the amounts of phase shifts, related to the cavity structure is expressed as

expression 1:

2D/λ+(φ1+φ2)/2λ=N expression 1

where D represents the optical distance between the reflecting surface of the first electrode 2 and the reflecting surface of the second electrode 7, λ, represents the maximum peak wavelength in the spectrum of light emitted from the organic EL element, φ1 represents the amount of phase shift at the reflecting surface of the first electrode 2, φ2 represents the amount of phase shift at the reflecting surface of the second electrode 7, and N represents a natural number.

Usually, each of the amount of the phase shift φ1 at the reflecting surface of the first electrode 2 and the amount of the phase shift φ2 at the reflecting surface of the second electrode 7 is it. Thus, in the case where the optical distance between the reflecting surface of the first electrode 2 and the reflecting surface of the second electrode 7 is set to an integral multiple of about ½ of the maximum peak wavelength λ, the cavity structure configured to reinforce light generated in the emissive layer 4 is obtained. This results in improvement in the efficiency of light emission. An organic EL element that emits blue light has a maximum peak wavelength λ of 400 nm to 480 nm. An organic EL element that emits green light has a maximum peak wavelength λ of 500 nm to 580 nm. An organic EL element that emits red light has a maximum peak wavelength λ of 600 nm to 730 nm.

The other is a constructive optical interference in which light emitted from an emission point in the emissive layer 4 and light reflected from the reflecting surface of the first electrode 2 are reinforced. The relationship among parameters, including the amounts of phase shifts, related to the optical interference is expressed as

expression 2:

2L/λ+φ1/2π=M expression 2

where L represents the optical distance between the reflecting surface of the first electrode 2 and the emission point in the emissive layer 4, λ represents the maximum peak wavelength of light that emerges, φ1 represents the amount of the phase shift at the reflecting surface of the first electrode 2, and M represents a natural number.

As described above, the amount of the phase shift φ1 at the reflecting surface of the first electrode 2 is π. Thus, in the case where the optical distance between the reflecting surface of the first electrode 2 and the emission point of the emissive layer 4 is an odd multiple of about ¼ of the maximum peak wavelength λ, light emitted from the emission point in the emissive layer 4 and light reflected from the reflecting surface of the first electrode 2 are reinforced. This results in improvement in the efficiency of light emission.

In an organic EL element having the cavity structure that satisfies expressions 1 and 2, the optical distance between the emission point and the reflecting surface of the second electrode 7 is an odd multiple of about ¼ of the maximum peak wavelength λ. In general, a thicker organic compound film results in a higher driving voltage. Thus, the optical distance between the emission point and the reflecting surface of the second electrode 7 is set to about ¼ of the maximum peak wavelength λ. The organic compound film has a refractive index of about 1.8. Thus, the distance between the emission point of the emissive layer 4 and the reflecting surface of the second electrode 7 (the interface between the second electrode 7 and the organic compound film) is in the range of about 55 nm to about 90 nm, depending on each emission color. The emission point is defined as a point of the highest emission intensity in an emission intensity distribution and is located on one surface of the emissive layer or in the middle of the emissive layer, depending on a material for the emissive layer and materials for the charge transport layers. For an organic EL element having the cavity structure, the distance between a surface of the emissive layer 4 adjacent to the first electrode and a surface of the second electrode 7 adjacent to the organic compound film is often in the range of 55 nm to 90 nm. The distance may be different in response to organic EL elements having different emission colors. For an organic EL element that emits blue light, the distance is in the range of 55 nm to 66 nm. For an organic EL element that emits green light, the distance is in the range of 69 nm to 80 nm. For an organic EL element that emits red light, the distance is in the range of 83 nm to 90 nm. The organic EL element that emits blue light has a short distance between a surface of the emissive layer 4 adjacent to the first electrode and the surface of the second electrode 7 adjacent to the organic compound film; hence, a buffer layer may be provided only in the organic EL element that emits blue light.

For an actual organic EL elements, in consideration of, for example, view angle characteristics, which is a trade-off for the efficiency of light emerging from the front face, the distance is not necessarily completely consistent with the thickness described above. The optical distance D or L may be shifted from a value that satisfies expression 1 or 2 by about ±λ/8.

That is, in the case where the optical distances D and L satisfy expressions 1′ and 2′, respectively, the optical interferences represented by the expressions are constructive optical interferences:

(4N−2(φ1+φ2)/π−1)λ/8<D<(4N−2(φ1+φ2)/π+1)λ/8 expression 1′, and

(4M−2φ1/π−1)λ/8<L<(4M−2φ1/π+1)λ/8 expression 2′.

In the case that a value of the optical distance D that satisfies expressions 1 and a value of the optical distance L that satisfies expressions 2 are denoted by Da and La, respectively, the optical distance D may be in the range of (Da−λ/16) to (Da+λ/16), and the optical distance L may be in the range of (La−λ/16) to (La+λ/16).

The components of the organic EL element according to aspects of the present invention will be described in detail below.

The substrate 1 may be composed of glass or plastic. The organic EL element according to aspects of the present invention is a top-emission organic EL element in which light emerges from a side of the organic EL element opposite the side adjacent to the substrate 1. Thus, the substrate 1 may have a low light transmittance or a high light transmittance.

The first electrode 2 may be formed of a single layer composed of, for example, gold, platinum, silver, aluminum, chromium, magnesium, or an alloy thereof. Alternatively, the first electrode 2 may be formed of a laminated film in which these layers are stacked. In particular, a thin film composed of silver or a silver alloy, which has higher conductivity and reflectivity than those of other metals, may be used. The first electrode 2 may have a thickness of 50 nm to 300 nm. For the first electrode 2, the interface between the first electrode 2 and the organic compound film serves as the reflecting surface of the first electrode 2. Alternatively, the first electrode 2 may have a structure in which a transparent conductive oxide layer composed of, for example, ITO, is stacked on the foregoing metal layer serving as a reflective layer. In this case, the interface between the reflective layer and the transparent conductive oxide layer functions as the reflecting surface.

The hole transport layer 3 plays a role in hole injection from the first electrode 2 and hole transport. Furthermore, a hole injection layer composed of, for example, copper phthalocyanine or vanadium oxide may be formed between the first electrode 2 and the hole transport layer, as needed. Examples of a low-molecular-weight material or polymer having the capability of injecting and transporting holes include, but are not limited to, triphenyldiamine derivatives, oxadiazole derivatives, porphyrin derivatives, stilbene derivatives, polyvinylcarbazole, and polythiophene. An electron-blocking layer having a small absolute value of the energy of the lowest unoccupied molecular orbital (LUMO) may be formed between the hole transport layer and the emissive layer, as needed. The hole transport layer 3 may have a thickness of 10 nm to 300 nm.

The emissive layer 4 may be suitably composed of any known light-emitting material. The light-emitting material may be a material that functions singly as an emissive layer by it self or may be a material that functions as a mixed layer containing a host material, an emissive dopant, a charge transport dopant, and so forth. The emissive layer 4 may have a thickness of 10 nm to 40 nm.

The electron transport layer 5 may be composed of a known material, for example, an aluminum quinolinol complex or a phenanthroline compound. A hole-blocking layer having a large absolute value of the energy of the highest occupied molecular orbital (HOMO) may be formed between the emissive layer and the electron transport layer, as needed. The electron transport layer 5 may have a thickness of 10 nm to 40 nm.

The electron injection layer 6 may be formed of a thin film composed of an alkali metal, an alkaline-earth metal, an alkali metal compound, or an alkaline-earth metal compound, the thin film having a thickness of 0.5 nm to 1 nm. For example, lithium fluoride (LiF), potassium fluoride (KF), or a magnesium oxide (MgO) may be used. Alternatively, the electron injection layer 6 may be formed of a layer composed of an organic compound containing a metal or a metal compound that serves as a donor (electron-donating) dopant. To improve the efficiency of electron injection, a metal having a low work function or a compound thereof may be used as a dopant. Examples of the metal having a low work function include alkali metals, alkaline-earth metals, and rare-earth metals. An alkali metal compound may be used because it is relatively easy to handle in air. For example, a cesium compound may be used as the alkali metal compound. Cesium carbonate is stable in air and is easy to handle. In this case, even if the thickness is increased, an increase in driving voltage is suppressed. A material having the capability of transporting electrons may be used as the organic compound for the electron injection layer. A known material, for example, an aluminum quinolinol complex or a phenanthroline compound, may be used. In the case of an electron injection layer composed of an organic compound that contains a donor (electron-donating) dopant, even if the thickness is increased, an increase in driving voltage is suppressed. The electron injection layer 6 may have a thickness of 10 nm to 40 nm.

The second electrode 7 may be formed of a thin film composed of, for example, gold, platinum, silver, aluminum, chromium, magnesium, or an alloy thereof. In particular, a thin film composed of silver or a silver alloy, which has higher conductivity and reflectivity than those of other metals, may be used. The second electrode 7 may have a thickness of 5 nm to 20 nm. If the second electrode 7 has a thickness of less than 5 nm, the cavity structure does not have a sufficient reflectivity (a reflectivity of 10% or more in the visible range of 380 nm to 780 nm). If the second electrode 7 has a thickness of 20 nm or more, a transmittance of 40% or more is not obtained in the blue wavelength range (400 nm to 480 nm).

Furthermore, the second electrode 7 having a thickness of 5 nm to 20 nm may be constituted by a thin metal film that is formed by a sputtering method. According to aspects of the present invention, only the second electrode 7 ensures the continuity of a cathode. However, in the case where a thin metal film having a thickness of 5 nm to 20 nm is formed by an evaporation method, it is difficult to form the thin metal film as a continuous film in the in-plane direction of the substrate 1, so that the film is disadvantageously broken at a bumpy portion such as a contact hole. This requires a strict control of the production process of the thin metal film. In contrast, for the case of the formation by the sputtering method, a continuous film is easily formed. Results of studies by the inventors demonstrate that for a thin film having a thickness of 5 nm to 20 nm, the sputtering method is performed for a short time, so that damage to the organic compound film by the sputtering method is negligible. Furthermore, the second electrode 7 formed as a continuous film can reduce damage to the organic compound film during the formation of the inorganic protective layer 9 described below.

The buffer layer 8 may be formed of an evaporated film substantially transparent to the emission colors of the organic EL element. The use of the transparent film results in a reduction in loss due to its optical absorption. The structure and effect of the buffer layer will be described in detail below. The term “transparent film” indicates that the transparent film has a light transmittance of 50% or more at the maximum peak wavelength in the spectrum of light emitted from the organic EL element.

The protective layer 9 may be composed of, for example, silicon nitride (SiN), silicon oxynitride (SiNOₓ), silicon oxide (SiO₂), indium-tin oxide (ITO), or indium-zinc oxide (In₂O₃-ZnO). The protective layer 9 may be formed as a dense moisture-resistant film by the sputtering method or a plasma-enhanced CVD method. The formation of the protective layer 9 results in a highly reliable organic EL element in which the underlying buffer layer and the organic compound film are less likely to be degraded by water. Furthermore, the protective layer 9 may have a thickness of 100 nm to 5000 nm in order to achieve performance as a protective layer.

A portion on the protective layer 9 may have any of various sealing structures and is not particularly limited. For example, after the formation of the protective layer 9, a coverage layer, composed of a thermosetting resin, having a thickness of 10 μm to 30 μm may be formed in case that a foreign substance is present on the protective layer 9. Furthermore, another protective layer may be formed thereon in order to prevent the penetration of water into the coverage layer. This sealing structure has good sealing performance that is not impaired even if a foreign substance is present. In this case, the protective layer 9 located under the coverage layer also functions to relieve stress due to the thermosetting resin and protect the organic compound film during a printing process. As another example of the sealing structure, after the formation of the protective layer 9, sealing may be performed with a glass cap provided with a drying agent in a glove box under a nitrogen atmosphere.

The structure and the effect of the buffer layer 8 according to aspects of the present invention will be described in detail below. For the top-emission organic EL element having a cavity structure, the second electrode 7 has a small thickness. Furthermore, as described above, the distance between the surface of the emissive layer 4 adjacent to the first electrode 2 and the surface of the second electrode 7 adjacent to the organic compound film is as short as 60 nm to 90 nm. Thus, in the case where the protective layer 9 is formed on the organic EL element by the sputtering method or the plasma-enhanced CVD method, significant damage from the sputtering method or the plasma-enhanced CVD method can occur. It was found that in such a structure, when the buffer layer 8 is formed before the formation of the protective layer 9, the buffer layer 8 has a significant effect as a damage resistant layer. The inventors have conducted experiments and have found the following typical effect of the buffer layer: in the case where light is emitted at 25 mA/cm², the degradation time the luminance is reduced by 1.5% is improved and found to be 1.2 to 4.0 times longer than that in the case where the buffer layer is not formed.

In the organic EL element according to aspects of the present invention, the buffer layer 8 is not detached, and the organic EL element has considerable flexibility in the choice of materials for the buffer layer. The reason for this is that the protective layer 9 according to aspects of the present invention is formed on the buffer layer 8. The protective layer 9 prevents not only the degradation of the organic EL element due to water but also the detachment of the buffer layer 8 due to moisture absorption. For example, even if a material which has excellent resistance to the sputtering method but which easily absorbs moisture is used for the buffer layer 8, the detachment of the layer is inhibited owing to the presence of the moisture-resistant protective layer 9. This provides considerable flexibility in the choice of materials for the buffer layer 8.

The buffer layer 8 is formed by the evaporation method. This method is less likely to damage the underlying film because the incident energy of evaporated particles is low and the underlying film (organic compound film) is not exposed to plasma, dissimilarly to the sputtering method and the plasma-enhanced CVD method. As the buffer layer 8 according to aspects of the present invention, it is difficult to use thermosetting resins and photocurable resins used for known coverage layer and so forth. These resins can cause problems of the degradation of the organic compound film due to heat or light applied during curing and the detachment of the film due to stress generated during the curing. Furthermore, there can be a problem of the permeation of a monomer or a solvent into the organic compound film through the second electrode 7 in a coating process. Moreover, there can be problems of contamination and the degradation of the organic compound film in a non-vacuum process.

The buffer layer 8 may be composed of an organic compound or an inorganic compound. In the organic EL element according to aspects of the present invention, a current is fed to the organic EL elements through only the second electrode 7; hence, the buffer layer 8 may have any conductivity and any thickness. In the case where the buffer layer 8 has a thickness of 30 nm or more and preferably 60 nm or more in view of resistance to the sputtering method, stable life properties are obtained. To reduce the production time, the buffer layer 8 may have a thickness of 150 nm or less.

The thickness d of the buffer layer 8 according to aspects of the present invention may satisfy expression 3 or expression 3′. In this case, light which passes through the second electrode 7 and which is reflected from the interface between the buffer layer 8 and the protective layer 9 is in phase with light that is reflected from the reflecting surface of the second electrode 7, thereby enhancing the effect of the cavity structure according to aspects of the present invention.

2nd/λ+φ/2π=m expression 3

(4m −2φ/π−1)λ/(8n)<d<(4m−2φ/π+1)λ/(8n) expression 3′

where λ represents the maximum peak wavelength in the spectrum of light emitted from the organic EL element, n represents a refractive index of the buffer layer 8 at the maximum peak wavelength λ, φ represents the amount of phase shift when light that has been emitted from the emissive layer is reflected from the interface between the buffer layer 8 and the protective layer 9, and m represents a natural number. Expression 3′ indicates that the thickness d is in the range of (1−λ/8) to (1+λ/8) where 1 represents an optical distance (=nd) that satisfies expression 3. The thickness d that satisfies expression 3′ also enhances the effect of the cavity structure according to aspects of the present invention.

As an organic compound for the buffer layer 8, for example, a material the same as any of the materials (a hole transport material, a light-emitting material, an electron transport material, and for forth) used for the layers in the organic compound film may be used. In this case, the number of types of material is not increased, thus reducing the cost.

As an inorganic compound for the buffer layer 8, for example, lithium fluoride (LiF) or magnesium fluoride (MgF₂) may be used. Each of Lithium fluoride and magnesium fluoride has a lower refractive index (about 1.4) than organic compound materials (with refractive indices of about 1.8). Hence, a large difference in terms of refractive index between the buffer layer 8 and the protective layer 9 may increase the reflectivity at the interface between the buffer layer 8 and the protective layer 9, thus enhancing the effect of the cavity structure described above. The difference in terms of refractive index between the buffer layer 8 and the protective layer 9 may be 0.5 or more.

The buffer layer 8 may have a laminated structure including two or more sublayers. In this case, the buffer layer 8 may have a laminated structure in which sublayers composed of an organic compound are stacked, a laminated structure in which sublayers composed of an inorganic compound, or a laminated structure in which a sublayer composed of an organic compound (e.g., electron transport material) and a sublayer composed of an inorganic compound (e.g., lithium fluoride) are stacked. As one of the sublayers included in the buffer layer, a low-refractive-index sublayer composed of, for example, lithium fluoride may improve the reflectivity at the interface between the sublayer composed of lithium fluoride and another sublayer. In the case where the thickness d of each of the plural sublayers satisfies expression 3 or expression 3′, the effect of the cavity structure is enhanced.

In the organic EL element according to aspects of the present invention, the total optical distance of the buffer layer 8 and the protective layer 9 may be an odd multiple of about ¼ of the maximum peak wavelength λ. That is, nd in expression 3 is set to (nld1+n2d2) where d1 represents the total thickness of the buffer layer 8, n1 represents the average refractive index of the buffer layer, d2 represents the thickness of the protective layer 9, and n2 represents the refractive index of the protective layer 9. The thickness of the buffer layer 8 and the thickness of the protective layer 9 are made to satisfy expression 3. This structure further enhances the effect of the cavity structure according to aspects of the present invention. In the case that a value of an odd multiple of about ¼ of the maximum peak wavelength λ is denoted by D3, the total optical distance of the buffer layer 8 and the protective layer 9 may be in the range of (D3−λ/8) to (D3+λ/8). A layer formed on the protective layer 9 may have a refractive index largely different from that of the protective layer 9 in order to increase the reflectivity at the interface between the protective layer 9 and the layer formed on the protective layer 9, depending on the sealing structure, e.g., another protective layer 9, a resin, a nitrogen atmosphere, and so forth.

In this embodiment, a structure in which the first electrode 2 on the substrate 1 serves as a positive electrode has been described. However, the present invention is not limited to this embodiment. For example, the first electrode (negative electrode), the electron injection layer, the emissive layer, the hole transport layer, the second electrode (positive electrode), the buffer layer, and the protective layer may be stacked, in that order, on the substrate 1.

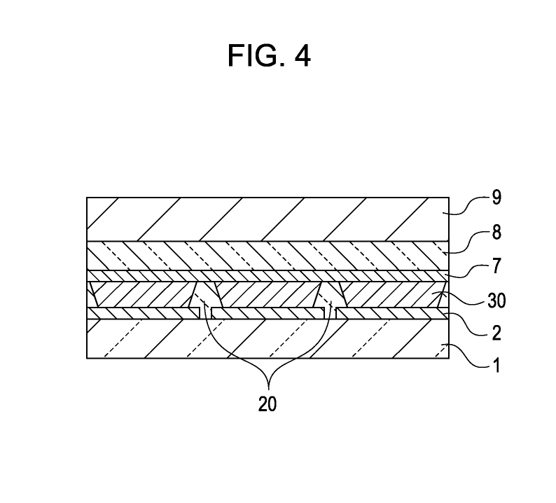

FIG. 4 is a cross-sectional view of a display including a plurality of organic EL elements, i.e., an organic EL element that emits blue light, an organic EL element that emits green light, and an organic EL element that emits red light. Each of the organic EL elements that emit the colored light beams may be formed of the organic EL element according to aspects of the present invention. Each of the organic EL elements includes the first electrode 2, an organic compound film 30 formed of a plurality of layers that includes an emissive layer, the second electrode 7, the buffer layer 8, and the protective layer 9, which are stacked, in that order, on the substrate 1. Furthermore, a partition member 20 is formed between the organic EL elements. The buffer layer 8 may have a thickness unique to each of the organic EL elements. For example, the buffer layer 8 may have a thickness such that expression 3 or expression 3′ is satisfied. Alternatively, the buffer layer 8 which has a thickness such that the efficiency of light emission of the organic EL element having the lowest luminous efficiency is improved and which is common to the organic EL elements may be formed. In the latter case, specifically, the buffer layer 8 has a thickness such that the maximum peak wavelength λ of the blue-light-emitting organic EL element satisfies expression 3 or expression 3′. This structure eliminates the need to form the buffer layer 8 by patterning for each color, thus leading to a simple process. The display can be used for television systems, personal computers, digital cameras, cellular phones, and so forth.

### Example 1

An organic EL element illustrated in FIG. 1 was produced by a method described below. An aluminum alloy (AlNd) film was formed by a sputtering method on the glass substrate 1 serving as a support so as to have a thickness of 100 nm. Then an ITO film was formed by the sputtering method so as to have a thickness of 70 nm, forming the first electrode 2 having a laminated structure. A partition member (not illustrated), composed of polyimide, having a height of 1 μm and a taper angle of 40° was formed. The substrate was subjected to ultrasonic cleaning with acetone and then isopropyl alcohol (IPA). The substrate was then boiled in IPA and dried. Surfaces of the substrate 1 were subjected to UV/ozone cleaning.

Copper phthalocyanine was deposited to form the hole transport layer 3 having a thickness of 50 nm. Alq₃ and DTBVi were co-deposited by an evaporation method (in a weight ratio of 95:5) to form the emissive layer 4 having a thickness of 30 nm. A bathophenanthroline compound was deposited on the emissive layer 4 to form the electron transport layer 5 having a thickness of 20 nm. The bathophenanthroline compound and cesium carbonate were co-deposited by the evaporation method in such a manner that the resulting layer had a cesium concentration of 8.3% by weight, forming the electron injection layer 6 having a thickness of 15 nm. Silver (Ag) was deposited by a thermal evaporation method on the electron injection layer 6 to form the second electrode 7 having a thickness of 16 nm. The distance between a surface of the emissive layer 4 adjacent to the first electrode 2 and a surface of the second electrode 7 adjacent to the organic compound film was set to 65 nm.

A material the same as the material used for the electron transport layer 5 was deposited by the thermal evaporation method on the second electrode 7 to form the buffer layer 8 having a thickness of 30 nm. SiN was deposited by CVD on the buffer layer 8 to form a protective layer having a thickness of 3 μm.

The organic EL element according to this example was driven at 25 mA/cm² to emit light. Then the degradation time the luminance was reduced by 1.5% was checked. The results demonstrated that the degradation time was improved and found to be about 2.5 times longer than that of an organic EL element in which the buffer layer 8 was not formed in the organic EL element according to this example.

In the resulting organic EL element, a dark spot and the detachment of the film attributed to water were not observed, thus improving life properties.

### Example 2

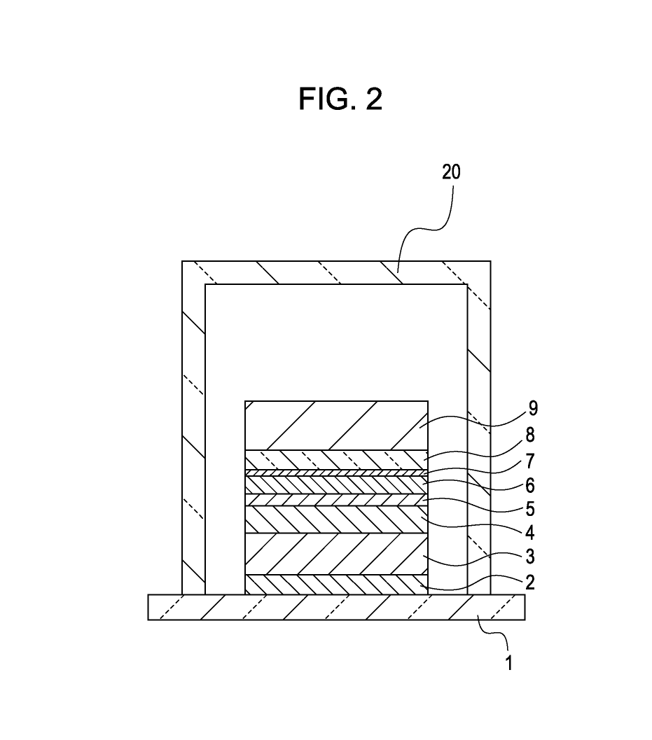

After the same process was performed up to the step of forming the electron injection layer 6 under the same conditions as in Example 1, an organic EL element according to this example was produced according to the following procedure. FIG. 2 is a cross-sectional view of the organic EL element according to Example 2.

Silver (Ag) was deposited by the sputtering method on the electron injection layer 6 to form the second electrode 7 having a thickness of 12 nm.

A material the same as the material used for the electron transport layer 5 was deposited on the second electrode 7 to form the buffer layer 8 having a thickness of 45 nm.

Indium zinc oxide was deposited by the sputtering method on the buffer layer 8 to form a protective layer having a thickness of 30 nm. The entire organic EL element was covered with a glass cap 40 containing a drying agent in a glove box under a nitrogen atmosphere. Note that in the case that a value of an odd multiple of about ¼ of the maximum peak wavelength λ (=460 nm) is denoted by D3, the total optical distance of the buffer layer 8 and the protective layer 9 was in the range of (D3−λ/8) to (D3+λ/8).

The luminous efficiency in this structure was improved and found to be 1.2 times higher than that of a structure in which the total optical distance of the buffer layer 8 and the protective layer 9 was outside the range of (D3−λ/8) to (D3+λ/8) described above.

The organic EL element according to this example was driven at 25 mA/cm² to emit light. Then the degradation time the luminance was reduced by 1.5% was checked. The results demonstrated that the degradation time was improved and found to be about 3 times longer than that of an organic EL element in which the buffer layer 8 was not formed in the organic EL element according to this example.

In the resulting organic EL element, a dark spot and the detachment of the film attributed to water were not observed, thus improving life properties.

In this example, the second electrode was formed of a thin metal film having a thickness as small as 12 nm. However, the second electrode was formed by the sputtering method and thus was a continuous film. It is therefore possible to establish highly reliable conduction without a break at bumpy portions such as a separation film and a contact hole.

### Example 3

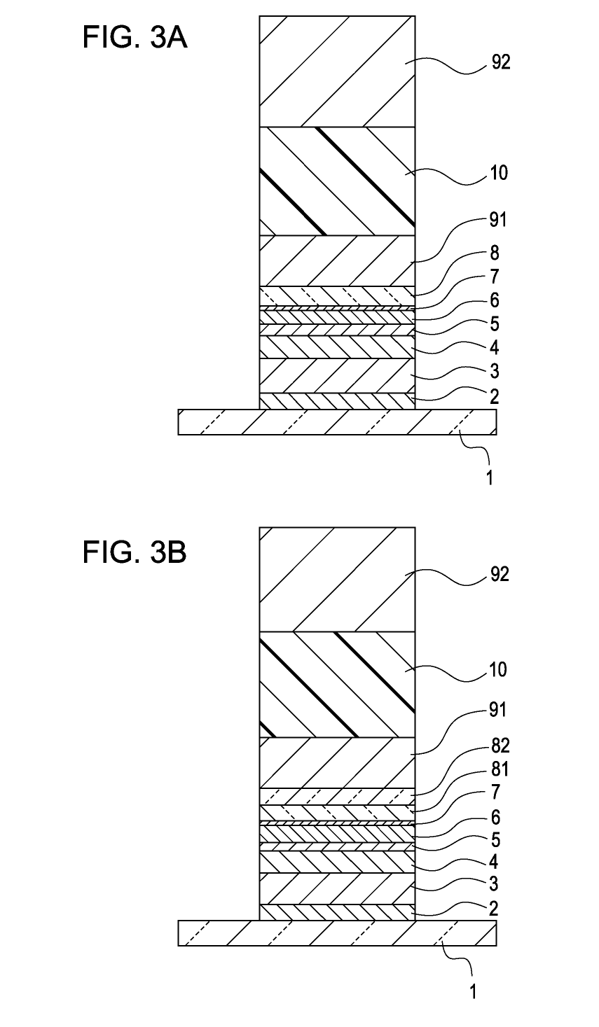

After the same process was performed up to the step of forming the buffer layer 8 under the same conditions as in Example 2, an organic EL element according to this example was produced according to the following procedure. FIG. 3A is a cross-sectional view of the organic EL element according to this example.

SiN was deposited by CVD on the buffer layer 8 to form a first protective layer 91 having a thickness of 150 nm. A thermosetting resin was applied thereon and cured to form a coverage layer 10 having a thickness of 30 μm. SiN was deposited by CVD on the coverage layer 10 to form a second protective layer 92 having a thickness of 1 μm.

The organic EL element according to this example was driven at 25 mA/cm² to emit light. The degradation time the luminance was reduced by 1.5% was improved and found to be about 3.2 times longer than that of an organic EL element in which the buffer layer 8 was not formed in the organic EL element according to this example.

In the resulting organic EL element, a dark spot and the detachment of the film attributed to water were not observed, thus improving life properties.

### Example 4

After the same process was performed up to the step of forming the second electrode 7 under the same conditions as in Example 2, an organic EL element according to Example 4 was produced according to the following procedure. FIG. 3A is a cross-sectional view of the organic EL element according to this example.

Lithium fluoride was deposited on the second electrode 7 to form the buffer layer 8 having a thickness of 80 nm.

SiN was deposited by CVD on the buffer layer 8 to form the first protective layer 91 having a thickness of 110 nm. The coverage layer 10, composed of a thermosetting resin, having a thickness of 30 μm was formed. SiN was deposited by CVD on the coverage layer 10 to form the second protective layer 92 having a thickness of 1 μm.

In this example, the thickness of the buffer layer 8 satisfied expression 3′. Light that was reflected from the interface between the buffer layer 8 and the first protective layer 91 was in phase with light that was reflected from the second electrode 7, thereby further enhancing the effect of the cavity structure. In the case where the buffer layer 8 of the organic EL element according to this example was composed of a bathophenanthroline compound (with a refractive index of 1.8) in place of lithium fluoride (with a refractive index of 1.4), the difference in terms of refractive index between the first protective layer 91 composed of SiN (with a refractive index of 2.0) and the buffer layer 8 was reduced. Hence, in this structure, the efficiency was reduced to 0.9 times.

In this Example, damage from the process for forming SiN by CVD was reduced by the buffer layer, thus achieving excellent life properties. Specifically, the organic EL element according to this example was driven at 25 mA/cm² to emit light. The degradation time the luminance was reduced by 1.5% was improved and found to be about 3.6 times longer than that of an organic EL element in which the buffer layer 8 was not formed in the organic EL element according to this example.

### Example 5

In this example, an organic EL element was produced as in Example 4, except that the structure of the buffer layer was different. Specifically, a material the same as the material used for the electron injection layer was deposited on the second electrode 7 to form a buffer sublayer 81 having a thickness of 70 nm. Lithium fluoride was deposited on the buffer sublayer 81 to form a buffer sublayer 82 having a thickness of 77 nm, the buffer sublayer 81 and the buffer sublayer 82 being included in the buffer layer 8. FIG. 3B is a cross-sectional view of the organic EL element according to this example.

In this example, the buffer sublayer 81 and the buffer sublayer 82 had different refractive indices. The difference in terms of refractive index therebetween resulted in an increase in reflectivity in the buffer layer. Furthermore, the thickness of each buffer layer satisfied expression 3′. Light that was reflected from the interface between the buffer layer 8 and the first protective layer 91 was in phase with light that was reflected from the second electrode, thereby further enhancing the effect of the cavity structure. The luminous efficiency was improved and found to be 1.2 times higher than that of an organic EL element in which the buffer sublayer 81 was not formed in the organic EL element according to this example.

In this Example, damage from the process for forming SiN by CVD was reduced by the buffer layer, thus achieving excellent life properties. Specifically, the organic EL element according to this example was driven at 25 mA/cm² to emit light. The degradation time the luminance was reduced by 1.5% was improved and found to be about 4.0 times longer than that of an organic EL element in which the buffer sublayer 81 and the buffer sublayer 82 were not formed in the organic EL element according to this example. While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-253076, filed Nov. 04, 2009, and Japanese Patent Application No. 2010-219483, filed Sep. 29, 2010, which are hereby incorporated by reference herein in their entirety.

### Reference Signs List

2 first electrode

4 emissive layer

7 second electrode

8 buffer layer

9 protective layer

1. An organic electroluminescent element comprising:
a first electrode;
an organic compound film including a plurality of layers that include an emissive layer;
a second electrode;
a protective layer, and
a buffer layer formed by an evaporation method between the second electrode and the protective layer, light emitted from the emissive layer emerging from the second electrode side,
wherein the second electrode is formed of a metal film having a thickness of 5 nm to 20 nm,
a distance between a surface of the emissive layer adjacent to the first electrode and a surface of the second electrode adjacent to the organic compound film is in the range of 55 nm to 90 nm, and
the protective layer is formed by a sputtering method or a plasma-enhanced chemical vapor deposition method.

2. The organic electroluminescent element according to claim 1,
wherein the buffer layer has a thickness of 60 nm or more.

3. The organic electroluminescent element according to claim 1, wherein the thickness d of the buffer layer satisfies the expression:
(4m−2φ/π−1)λ/(8n)<d<( 4m −2φ/90 +1)λ/(8n)
where λ represents the maximum peak wavelength in the spectrum of light emitted from the organic electroluminescent element, n represents a refractive index of the buffer layer at the maximum peak wavelength λ, φ represents the amount of phase shift when light that has been emitted from the emissive layer is reflected from the interface between the buffer layer and the protective layer, and m represents a natural number.

4. The organic electroluminescent element according to claim 1,
wherein the buffer layer includes a plurality of sublayers.

5. The organic electroluminescent element according to claim 1, wherein the buffer layer comprises a material the same as any one of the materials contained in the plural layers included in the organic compound film.

6. The organic electroluminescent element according to claim 1, wherein the buffer layer comprises lithium fluoride or magnesium fluoride.

7. The organic electroluminescent element according to claim 1, wherein the protective layer has a thickness of 100 nm to 5000 nm.

8. The organic electroluminescent element according to claim 1, wherein the second electrode is formed by the sputtering method so as to have a thickness of 5 nm to 20 nm.

9. The organic electroluminescent element according to claim 1, wherein the difference in terms of refractive index between the buffer layer and the protective layer is 0.5 or more.

10. A display comprising:
a blue-light-emitting organic electroluminescent element;
a green-light-emitting organic electroluminescent element; and
a red-light-emitting organic electroluminescent element,
wherein each of the blue-, green-, and red-light-emitting organic electroluminescent elements is the organic electroluminescent element according to claim 1.

11. The display according to claim 10, wherein the buffer layers of the respective blue-, green-, and red-light-emitting organic electroluminescent elements are integrally arranged and have the same thickness.

12. The display according to claim 10, wherein in the blue-light-emitting organic electroluminescent element, the distance between a surface of the emissive layer adjacent to the first electrode and a surface of the second electrode adjacent to the organic compound film is in the range of 55 nm to 64 nm.

13. The display according to claim 12,
wherein in the green-light-emitting organic electroluminescent element, the distance between a surface of the emissive layer adjacent to the first electrode and a surface of the second electrode adjacent to the organic compound film is in the range of 69 nm to 80 nm, and
wherein in the red-light-emitting organic electroluminescent element, the distance between a surface of the emissive layer adjacent to the first electrode and a surface of the second electrode adjacent to the organic compound film is in the range of 83 nm to 90 nm.

14. The display according to claim 11, wherein the thickness d of the buffer layers satisfies the following expression:
(4m−2φ/π−1)λ_{B}/(8n)<d<(4m −2φ/π+1)λ_{B}/(8n)
where λ_{B} represents the maximum peak wavelength in the spectrum of light emitted from the blue-light-emitting organic electroluminescent element, n represents a refractive index of the buffer layers at the maximum peak wavelength λ_{B}, φ represents the amount of phase shift when light that has been emitted from the emissive layer is reflected from the interface between the buffer layer and the protective layer, and m represents a natural number.

15. An organic electroluminescent element comprising:
a first electrode;
an organic compound film including a plurality of layers that include an emissive layer;
a second electrode;
a protective layer, and
a buffer layer formed by an evaporation method between the second electrode and the protective layer, light emitted from the emissive layer emerging from the second electrode side,
wherein the second electrode is formed of a metal film having a thickness of 5 nm to 20 nm,
the protective layer is formed by a sputtering method or a plasma-enhanced chemical vapor deposition method, and
the buffer layer has a thickness of 60 nm or more.

16. An organic electroluminescent element comprising:
a first electrode;
an organic compound film including a plurality of layers that include an emissive layer;
a second electrode;
a protective layer, and
a buffer layer formed by an evaporation method between the second electrode and the protective layer, light emitted from the emissive layer emerging from the second electrode side,
wherein
a distance between a surface of the emissive layer adjacent to the first electrode and a surface of the second electrode adjacent to the organic compound film is in the range of 55 nm to 90 nm, and
the protective layer is formed by a sputtering method or a plasma-enhanced chemical vapor deposition method.
